(19) United States
(12) Patent Application Publication
(10) Pub. No.: US 2017/0271397 A1
(43) Pub. Date: Sep. 21, 2017

(54) Anti-Reflective Treatment Of The Rear Side Of A Semiconductor Wafer

(71) Applicant: X-FAB SEMICONDUCTOR FOUNDRIES AG, Erfurt (DE)

(72) Inventor: Daniel GAEBLER, Sulzbach (DE)

(21) Appl. No.: 15/502,212

(22) PCT Filed: Aug. 8, 2014
(86) PCT No.: PCT/IB2014/063804

§ 371 Date: Jun. 7, 2017

(51) Int. Cl. H01L 27/146

(52) U.S. Cl. CPC H01L 27/14685; H01L 27/14687; H01L 27/14689; H01L 27/14643; H01L 27/1462; H01L 27/1464

(57) ABSTRACT

A method for producing a semiconductor wafer, in which an optical anti-reflective layer (4) is formed on the backside of the wafer in order to optimize optical access (17) to or from CMOS devices (10) through the backside (3₂) of the wafer (1). The CMOS devices (10) are produced only after formation of an anti-reflective layer (4), the etching stop layers (5, 6) formed thereon, the bonding layer (7) and the carrier wafer (8) bonded thereto. After formation of the CMOS devices, the etching stop layers (5, 6), the bonding layer (7) and the bonded carrier wafer (8) are thinned and removed, at least selectively, by grinding or by means of lithography (16) or masked etching.

### BACKGROUND OF THE INVENTION

1. Field of the Invention

The invention relates to production processes of optically active semiconductor devices. In particular, but not exclusively, it relates to methods for CMOS devices, in which photosensitive or photogenic devices are formed in the face of a CMOS wafer, the backside of which is thinned and anti-reflective so that the photosensitive or photogenic devices are able to receive or emit their light through the backside of the wafer (depending on the direction).

2. Description of the Related Art

Various solutions for achieving anti-reflection of the face (device face) of a subarea of a CMOS wafer are known. Some of them also consider, apart from the optical anti-reflection, the electrical behavior of the anti-reflective interface, cf. WO 2011/039568 (X-Fab Semiconductor) or WO 2004/021452 (X-Fab Semiconductor).

The processing of the backside of CMOS wafers is of increasing interest since CMOS integration increasingly moves into the third dimension. The intended aim is increasing the device density by using means going beyond a further development of lithography and exploiting hitherto unused surfaces for that purpose. From the field of image sensors, it is already known to arrange the pixel sensors of an image sensor such that they sense the illumination through the wafer backside (so-called “backside illumination”, also referred to as BSI). In such image sensors, an anti-reflective layer is formed on the wafer backside in order to avoid light losses and to increase the photosensitivity of the image sensor. Such a CMOS image sensor with backside anti-reflection is described in DE 10 2011 014 010 A1 (Taiwan Semiconductor).

In known backside anti-reflection methods, a separate additional process step is performed, in which process conditions (e.g. temperature, process materials) are to be selected such that the CMOS devices are not affected during the anti-reflection steps. Moreover, the known backside anti-reflection solutions may be suitable for image sensors, when the circuit components on the face are substantially homogenous, and an anti-reflective coating is to be uniformly applied to a wide area of the backside, but is not suitable for general CMOS circuits, such as processors, application-specific semiconductor devices (ASIC) and such like, in which the photosensitive or photogenic devices form an arbitrary or small portion of the entire circuit components. A further disadvantage of the conventional anti-reflection methods is that the selection of anti-reflection process parameters and materials is limited since this selection is required to consider the CMOS devices on the face. This limitation may result in the fact that the selected process parameters and materials will not be ideal for anti-reflection.

### SUMMARY OF THE INVENTION

It is an object of the invention to enable anti-reflection of a subarea of the backside of a wafer in a CMOS process with the aim of providing a defect-free silicon interface for an optimum electrical behavior thereof, wherein any CMOS devices formed on the face will not be affected or damaged by side effects of the anti-reflection process steps.

For this purpose, the invention provides a method for producing a semiconductor device, the method comprising a production step wherein a plurality of circuit components are produced on a face of a base wafer, and the circuit components comprise at least one photosensitive or photogenic optoelectronic component; a first anti-reflection step, whereas at least one dielectric anti-reflective layer is created on a backside of the base wafer; wherein the first anti-reflection step is performed prior to the production step. Variants of the method according to the invention are covered by dependent claims.

Since the anti-reflective layer is applied prior to the CMOS process, the method steps associated therewith are not contingent on the presence of an existing CMOS structure. The anti-reflective layer can be deposited, for example, at a higher temperature than if CMOS devices were present, which may result in an optically and mechanically higher quality of the anti-reflective layer. Moreover, the anti-reflective layer protects the silicon interface of the wafer backside from damage or impurities during and after processing of the face.

In the claims, it is differentiated between a “backside” and a “face” of the wafer. These relative terms refer to the final sides of the processed structure, wherein the circuit components (e.g. CMOS devices) are located on the face of the base wafer and the anti-reflective coating is located on the backside thereof

These terms do not refer especially to the common definitions of the “face” and “backside” of the SOI wafer, which can be used as a base wafer. In the example, the SOI wafer can, for example, be arranged such that the CMOS devices are produced on the backside of the SOI wafer (according to the common designation of the sides of an SOI wafer). This “backside” of the SOI wafer is nevertheless called “face” since the latter refers to the context of the entire structure. Similarly, the anti-reflective layer is applied to the side of the SOI wafer that would usually be referred to as the “face” of the SOI wafer; this side is referred to as “backside” for the same reason.

The method according to the invention will be exemplarily explained in greater detail below with reference to the drawings. The examples are still examples even if the words “for example” or “especially” do not appear before each term.

### BRIEF DESCRIPTION OF THE DRAWINGS

FIG. 1 shows, in schematic cross-section, a first anti-reflection process in a method.

FIG. 2 shows, in schematic cross-section, a resulting wafer structure after the anti-reflection process of FIG. 1.

FIG. 3 shows, in schematic cross-section, a first CMOS process.

FIG. 4 shows, in schematic cross-section, a second CMOS process.

FIGS. 5a and 5b show, in schematic cross-section, two variants of a thinning and etching treatment of the wafer according to the invention after the CMOS process.

FIGS. 6a and 6b show, in schematic cross-section, a further etching treatment of the wafer.

FIGS. 7a and 7b show, in schematic cross-section, still a further etching treatment of the wafer.

FIGS. 8a and 8b show, in schematic cross-section, yet a further etching treatment of the wafer.

FIG. 9 shows, in schematic cross-section, the stabilizing preparation of the treated wafer via a second carrier wafer according to one variant of the method.

FIG. 10 shows, in schematic cross-section, a thinning step according to the variant illustrated in FIG. 9.

### DETAILED DESCRIPTION OF PREFERRED EMBODIMENTS

The Figures are illustrative examples providing a better understanding and explanation of the claimed invention. They do not constitute limitations of the claimed invention. In these Figures, the same reference numerals are used for identical elements or elements similar in function.

In the Figures, the dimensions are not to scale, neither absolute nor relative scale.

In this description, the English term “wafer” is used. This term is to be understood as referring to a semiconductor disk or board or chip. A wafer may be composed of, for example, monocrystalline silicon. Even though the example of CMOS and silicon is explained below, the description is supposed to include also other production technologies. The term “deposition” is to be understood in a general sense und includes the creation of layers in general. When a first layer is located “on top” of a second one, it is not excluded that one or more further layers are located there between. The term “anti-reflection” is not to be understood in the narrowest sense of a reduction of the reflection of the wafer; the term may also include other optical functions, such as light diffusion, changing the index of refraction, filtering out specific wavelengths, etc.

In the following and in the claims, it is differentiated between a “backside” and a “face” of the wafer. These relative terms refer to the final sides of the processed structure, wherein the circuit components (e.g. CMOS devices) are located on the face of the base wafer and the anti-reflective coating is located on the backside thereof. These terms do not refer especially to the common definitions of the “face” and “backside” of the SOI wafer which is used as a base wafer in the following embodiment. In this embodiment, the SOI wafer can, for example, be arranged such that the CMOS devices are produced on the backside of the SOI wafer (according to the common designation of the sides of an SOI wafer). This “backside” of the SOI wafer is nevertheless called “face” since the latter refers to the context of the entire structure. Similarly, the anti-reflective layer is applied to the side of the SOI wafer that would usually be referred to as the “face” of the SOI wafer; this side is called “backside” for the same reason.

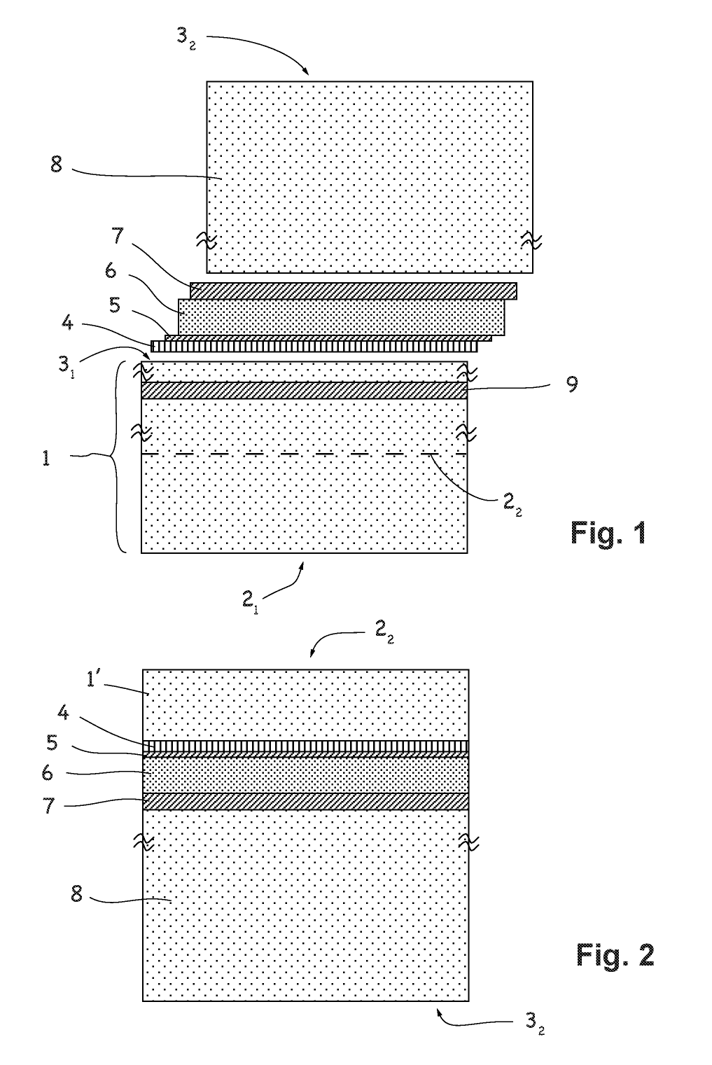

FIG. 1 shows, by way of example, a silicon-on-insulator (SOI) or smart-cut wafer 1 which is referred to as base wafer in the following. Such a base wafer 1 is suitable for the production of CMOS circuits on a silicon interface 2₂, which is subsequently exposed by removing a part of the base wafer 1 on the face 2₁ thereof.

A so-called buried oxide layer 9 is illustrated in the example of FIG. 1. According to this example, a thin oxide, e.g. less than 10 nm, especially in the range between 2 nm and 3 nm, is initially created on the backside 3₁ of the base wafer 1. This oxide layer (not shown) can be created, for example, under the same process conditions which are used for the formation of gate oxide in the CMOS devices yet to be produced. The oxide layer, inter alia, serves the purpose of protecting the silicon surface on the backside 3₁ from impurities and uncontrolled oxidation.

An anti-reflective layer 4 (e.g. SiC, or preferably Si₃N₄) is deposited on the “thin” oxide with a thickness corresponding to its purpose, typically between 10 nm and 60 nm, for example 42 nm, if good anti-reflection performance is to be achieved in a light wavelength range of 400 nm. When depositing the anti-reflective layer 4, the process parameters can be selected for optimum optical performance (e.g. anti-reflection, translucence, index of refraction, homogeneity) instead of having to pay attention to protecting devices on the face 2₂ of the wafer, since there are no such device present yet.

An Si₃N₄ layer 4 can be deposited, for example, at a temperatures higher than the temperature which would be suitable for the protection of present CMOS devices. As a result of the higher temperature, the resulting Si₃N₄ layer 4 may have a higher quality, e.g. having a lower hydrogen content.

The deposition may also be performed more precisely with respect to the relevant anti-reflection process parameters. Planarity and homogeneity of the anti-reflective layer 4 can be optimized, for example, by using a suitable deposition speed and duration.

According to the illustrated example, a thin silicon oxide layer 5 is deposited on the Si₃N₄ layer 4. The exemplary thin silicon oxide layer 5, also referred to as second etching stop layer, has the purpose of stopping an etching of the polysilicon layer 6 which is subsequently applied to the second etching stop layer 5. At the end of the process, a remaining rest of the second etching stop layer 5, together with the first anti-reflective layer 4, may act as an anti-reflective layer system. The second etching stop layer 5 is thus preferably very thin, e.g. 2 nm to 10 nm, however, is strong enough to achieve a stable process control of a polysilicon etching. If the thinned second etching stop layer 5, possibly together with the anti-reflective layer 4, is supposed to act as an anti-reflective layer system, the thickness of the anti-reflective layer 4 (as well as the optical layer properties thereof, such as index of refraction, etc.) should be chosen such that the anti-reflective layer system as a whole has the desired optical properties.

As mentioned above, a polysilicon layer 6 is deposited on the second etching stop layer 5. This polysilicon layer 6 is also referred to as first etching stop layer 6 in the following and serves the purpose of stopping etching of the one or more bonding layers 7 formed thereon, e.g. oxide or nitride. The thickness of the first etching stop layer 6 is, for example, between 100 nm and 300 nm which results from the requirement as an end stop for the etching of the bonding layer 7 located thereon.

Thus, a further silicon oxide layer or silicon nitride layer, referred to as bonding layer 7 in the following, which serves the purpose of bonding a carrier wafer 8 thereto, is deposited on the second etching stop layer 6. The bonding layer 7 is preferably several hundred nm thick, especially between 150 nm and 250 nm, and has a very smooth surface to enable a flawless bonding of the carrier wafer 8. To ensure the planarity of the bonding layer 7, a further process step, e.g. polishing the bonding layer 7, can be performed prior to bonding the carrier wafer 8.

The surface of the bonding layer 7 is—as mentioned—bonded to a carrier wafer 8. Then, the material of the base wafer 1 is removed except for its device wafer portion 1′ or, in case the base wafer 1 is a smart-cut wafer, it is reduced to its device wafer portion 1′ by the smart-cut process. The thus created new silicon interface 2₂ is used as the wafer face surface in the subsequent standard CMOS process.

The wafer processed to this extent is schematically illustrated in FIG. 2. The exposed silicon interface 2₂ of the SOI or smart-cut base wafer 1′ is ready for the CMOS production; the anti-reflective layer 4 is already present, however, still covered; etching stop layers 5 and 6 are available for later processing of the wafer backside 3₂; and the entire wafer structure is stabilized for the subsequent CMOS production by the bonded carrier wafer 8 and the bonding layer 7.

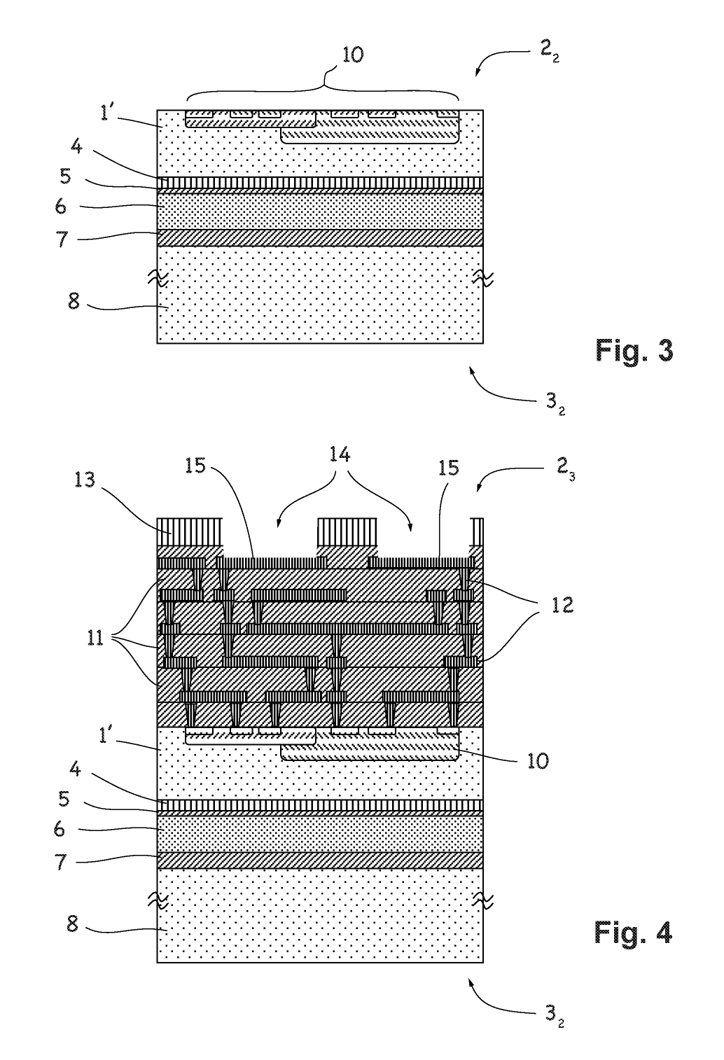

FIGS. 3 and 4 show an exemplary CMOS production on the prepared silicon interface 2₂. CMOS devices 10 comprising one or more optoelectronic elements are formed in the remaining base wafer 1′. Then, insulation layers 11, metal platings 12 and a passivation layer 13 are formed. Apertures 14 to the bond pads 15 are formed as well. Thus, a new face 2₃ of the wafer is accomplished.

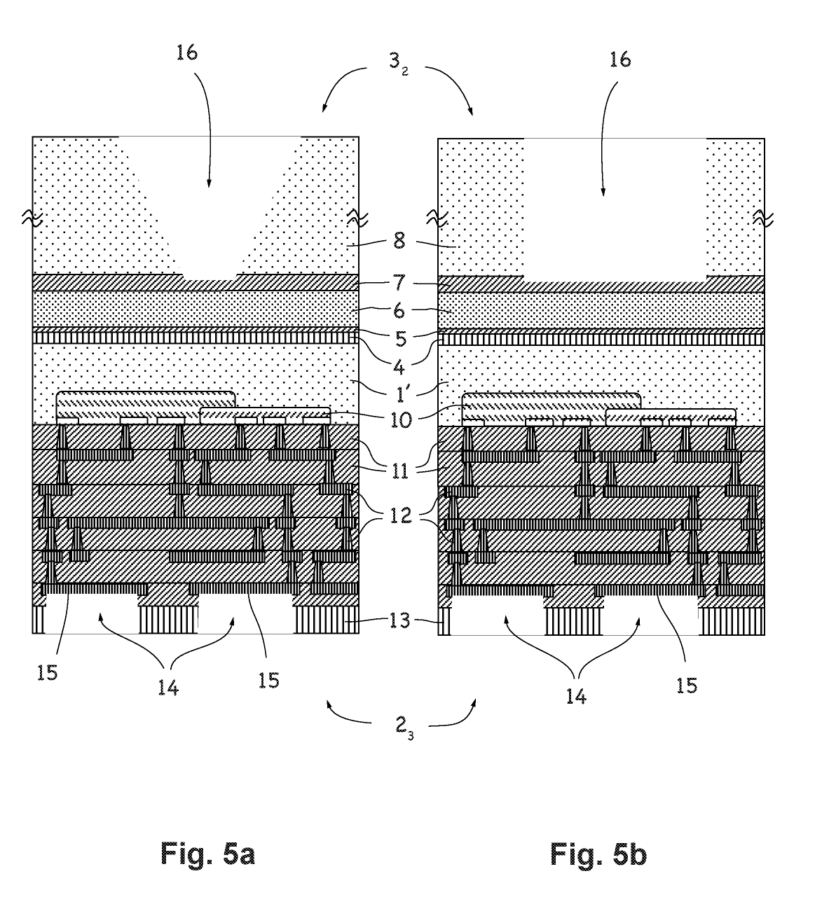

After completion of the CMOS process sequence, the bonded wafer is turned over, as shown in FIGS. 5a and 5b, so that its backside 3₂ can be processed.

Now, the carrier wafer 8 can be removed either completely or partially, e.g. by means of a lithography mask.

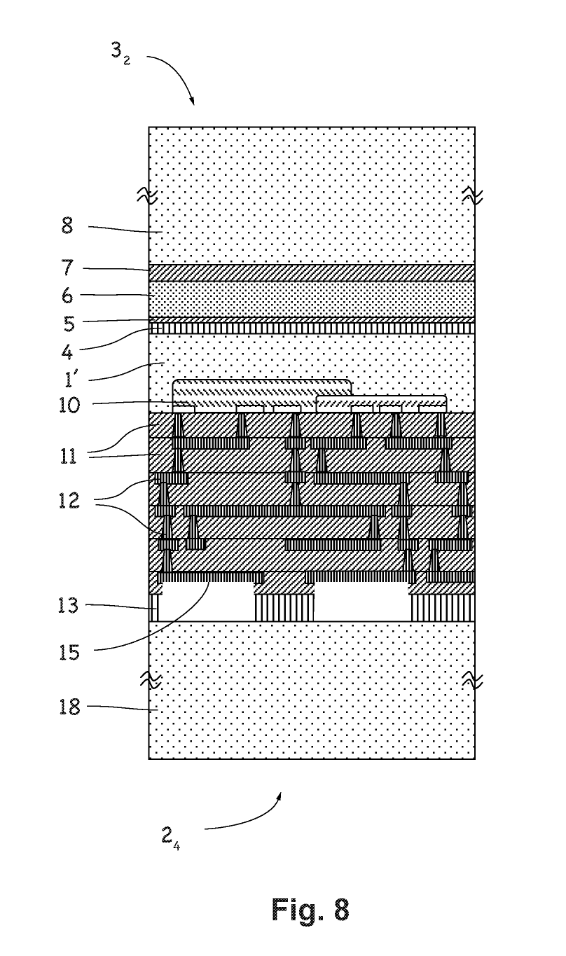

FIGS. 5 to 7 show a partial removal of the carrier wafer 8. Whereas FIGS. 8 to 10 show a complete removal of the carrier wafer.

According to FIGS. 5a and 5b, the carrier wafer 8 can initially be thinned (by grinding and/or polishing) and prepared for lithography. Then, the light guides 16 are selectively etched through the remaining silicon of the carrier wafer 8. The silicon etching of the carrier wafer 8 can be stopped in the bonding layer 7; FIGS. 5a and 5b show tapered and straight-walled etching examples. A wet etching (e.g. potassium hydroxide, KOH) or dry etching can be applied.

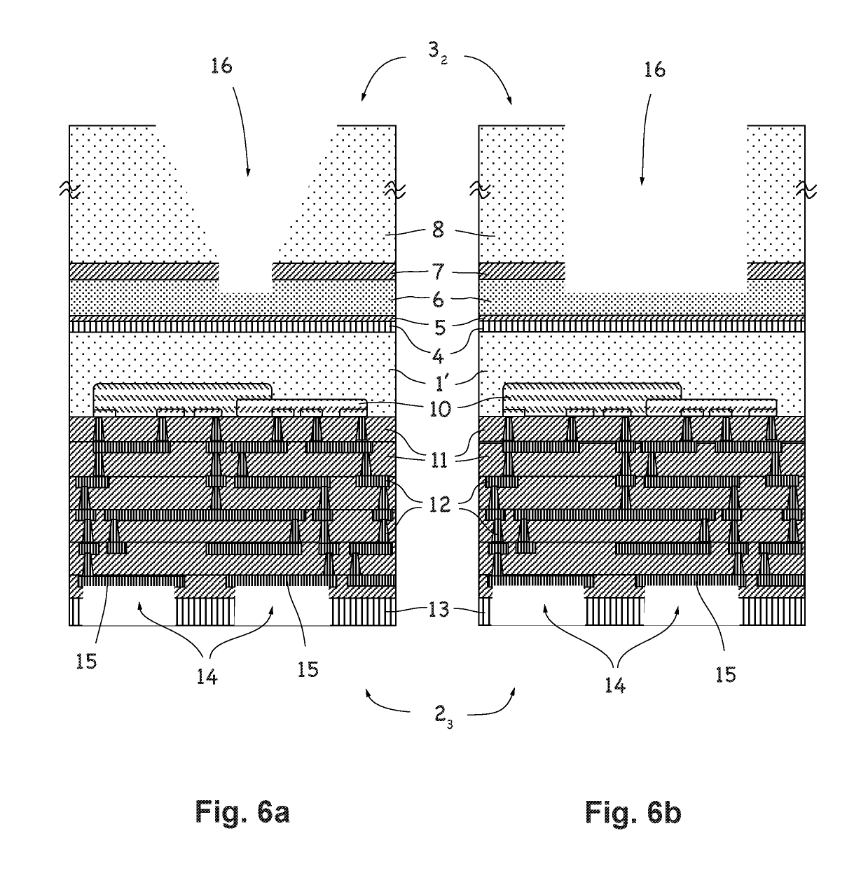

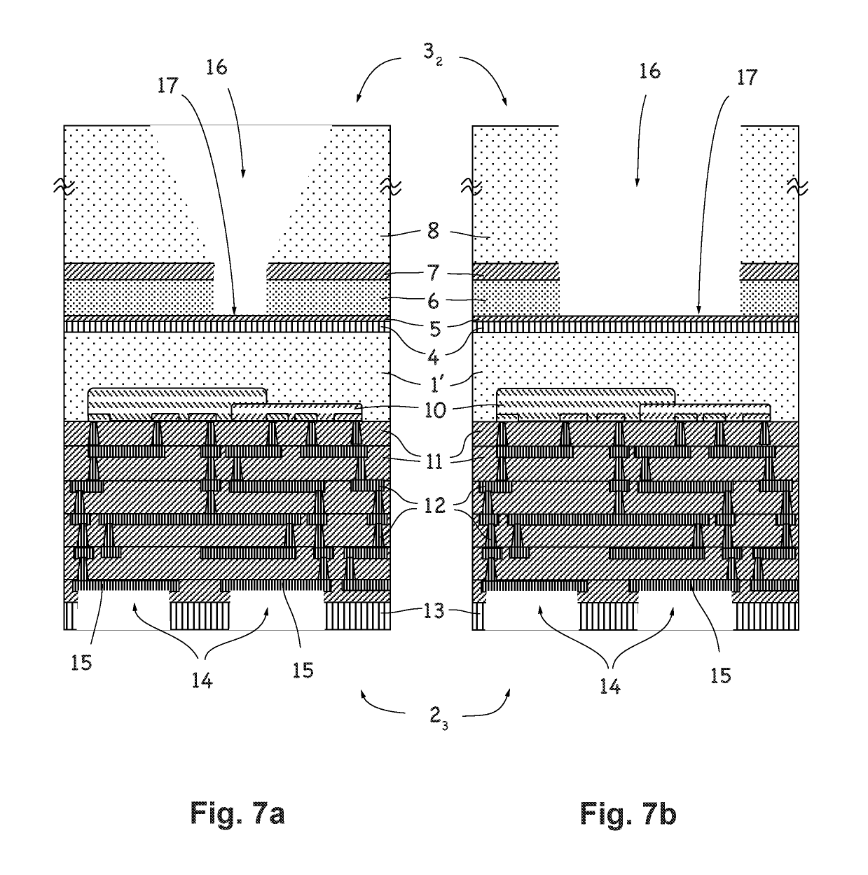

The bonding layer 7 can then be etched with a stop on the first etching stop layer 6 (polysilicon layer) (FIGS. 6a and 6b) which, in turn, can be etched very precisely and selectively with a stop on the second etching stop layer 5 (silicon oxide layer) (FIGS. 7a and 7b). Thus, an anti-reflective area 17 of the wafer backside 3 is exposed, the covered silicon interface of which having been protected throughout the entire process flow and thus has a very high quality.

For stabilizing the remaining wafer, especially in the case of a complete removal of the first carrier wafer 8, preferably a second carrier wafer 18 is applied to the wafer face, as in FIG. 8, which can be removed at a later stage to enable electrical contacting to the bond pads 15. The wafer thus has a new face 2₄.

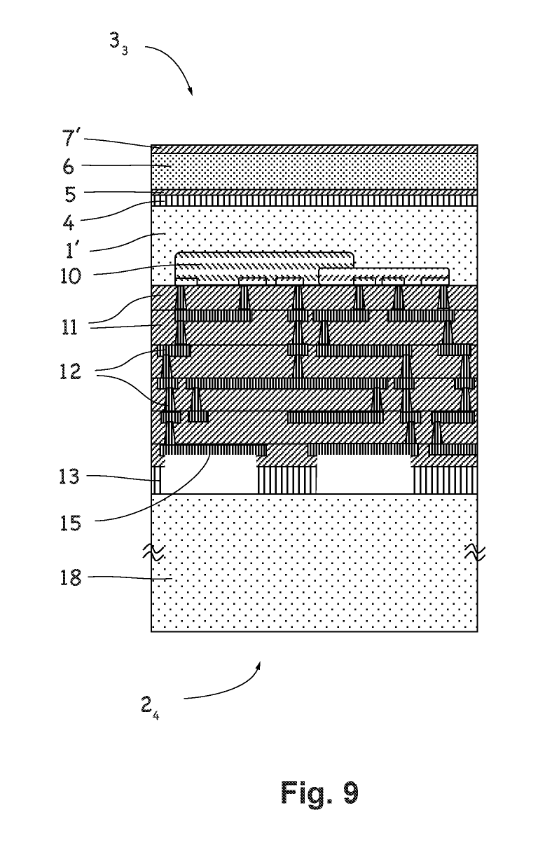

FIG. 9 shows how the first carrier wafer 8 has been removed, e.g. by grinding, up to the bonding layer 7. Then, the remaining rest 7′ of the bonding layer 7 is removed via or by an oxide etching process on the new backside surface 3₃ up to the first etching stop layer 6 (polysilicon), whereupon the first etching stop layer 6 is removed with high precision by means of a very precise polysilicon etching process up to the second etching stop layer 5 (silicon oxide).

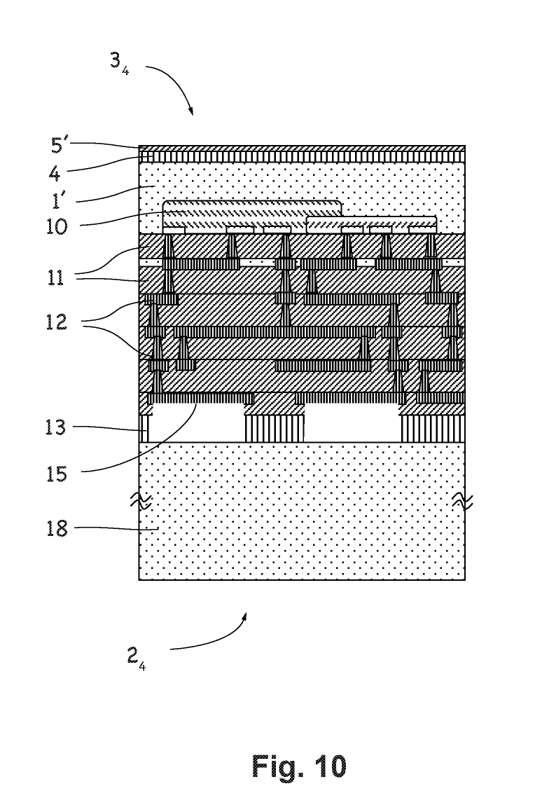

The exemplary result is shown in FIG. 10: The new backside 3₄ of the wafer is now protected by a very uniform, high-quality anti-reflective layer 4, 5′ of e.g. 10 nm to 60 nm of Si₃N₄ and 1 nm to 5 nm of the oxide layer 5′.

1. A method for producing a semiconductor device, the method comprising the following steps:
a production step wherein a plurality of circuit components (10) are produced on a face (22) of a base wafer (1′) and the circuit components (10) comprise at least one photosensitive or photogenic optoelectronic component (10);
a first anti-reflection step wherein at least one dielectric anti-reflective layer (4, 5′) is created on a backside (31) of the base wafer (1′);
wherein the first anti-reflection step is performed prior to the production step.

2. The method according to claim 1, further comprising at least one coating step, in which at least one further layer (5, 6, 7) is created on or applied to the anti-reflective layer (4), wherein the at least one further layer comprises a second anti-reflective layer (5′) or at least one etching stop layer, and wherein the at least one coating step is performed subsequent to the anti-reflection step and prior to the production step.

3. The method according to claim 2, further comprising at least one first application of a first carrier wafer (8) to the backside (31) of the base wafer (1), wherein the first application of the first carrier wafer (8) is performed subsequent to the anti-reflection step and prior to the production step.

4. The method according to claim 3, wherein the at least one further layer (5, 6, 7) comprises a bonding layer (7), and wherein the application of the first carrier wafer (8) includes bonding the first carrier wafer (8) to the bonding layer (7).

5. The method according to claim 4, further comprising at least one thinning step performed subsequent to the production step, wherein a thickness of the applied first carrier wafer (8) is reduced.

6. The method according to claim 5, wherein the thinning step comprises a substantially uniform or complete removal of the first carrier wafer (8) from the backside (32) of the base wafer (1′).

7. The method according to claim 1, further comprising a second application of a second carrier wafer (18) to the face (23) of the base wafer (1′), wherein the second application is performed subsequent to the production step and prior to the thinning step.

8. The method according to claim 7, wherein the second carrier wafer (18) is removed, at least in part, subsequent to the thinning step.

9. The method according to claim 1, further comprising a selective removal of material of the at least one further layer (5, 6, 7) or of the thinned first carrier wafer (8) in at least one selected location (17) on the backside (32) of the base wafer (1′), wherein the at least one selected location (17) on the backside (32) is located opposite to the at least one optoelectronic component (10) formed on the face (22) of the base wafer.

10. The method according to claim 9, wherein the selective removal comprises a masked method or a lithographic method.

11. The method according to claim 9, wherein tapered light windows (16) are opened through the at least one further layer (5, 6, 7) or through the thinned first carrier wafer (8) up to the at least one selected location (17) of the anti-reflective layer (4, 5′).

12. The method according to claim 1, wherein the production step includes a CMOS method, and the circuit components (10) comprise CMOS devices.

13. The method according to claim 1, wherein the anti-reflective layer (4, 5′) includes an Si₃N₄ layer having a thickness of 10 nm to 60 nm.

14. The method according to claim 1, wherein the second anti-reflective layer (4, 5′) includes an oxide layer (5′) having a thickness of 1 nm to 5 nm.

15. (canceled)

16. A method of producing a semiconductor device, the method comprising the following steps:
providing a base wafer having a face side and a backside; and comprising
a first anti-reflection providing step comprising creating at least one dielectric anti-reflective layer on the backside of the base wafer; and
a production step comprising producing a plurality of circuit components on the face of the base wafer, wherein the circuit components comprise at least one photosensitive optoelectronic component.

17. A method of producing a semiconductor device, the method comprising the following steps:
providing a base wafer having a face side and a backside;
and comprising
a first anti-reflection providing step comprising creating at least one dielectric anti-reflective layer on the backside of the base wafer;
a production step comprising producing a plurality of circuit components on the face of the base wafer, wherein the circuit components comprise at least one photogenic optoelectronic component.
